(19) United States
(12) Patent Application Publication
(10) Pub. No.: US 2026/0230059 A1
(43) Pub. Date: Aug. 6, 2026

(54) FREQUENCY FILTER AND METHOD OF MANUFACTURING FREQUENCY FILTER

(71) Applicant: Mitsubishi Electric Corporation, Tokyo (JP)

(72) Inventors: Shin UEGAKI, Tokyo (JP); Yoshitaka KAJIYAMA, Tokyo (JP)

(73) Assignee: Mitsubishi Electric Corporation, Tokyo (JP)

(21) Appl. No.: 19/147,722

(22) PCT Filed: Mar. 3, 2023
(86) PCT No.: PCT/JP2023/007933

§ 371 Date: Jul. 14, 2025

(51) Int. Cl. H03H 9/46; H03H 9/24

(52) U.S. Cl. CPC H03H 9/46; H03H 9/24

(57) ABSTRACT

A high-frequency filter operated in a high frequency range is provided. The frequency filter includes a medium layer, an input-side comb-tooth electrode, and an output-side comb-tooth electrode. The medium layer has flexoelectric characteristics. The input-side comb-tooth electrode is provided on the medium layer. The output-side comb-tooth electrode is provided on the medium layer. The medium layer can generate an elastic wave in the medium layer in accordance with an input electrical field in the input-side comb-like electrode and an output electrical field corresponding to an elastic wave in the output-side comb-tooth electrode.

### TECHNICAL FIELD

The present disclosure relates to a frequency filter and a method of manufacturing the frequency filter.

### BACKGROUND ART

A frequency filter is mounted to a wireless communication system. Patent Document 1 discloses a surface acoustic wave (SAW) filter as the frequency filter.

### PRIOR ART DOCUMENTS

### Patent Document(s)

Patent Document 1: Japanese Patent Application Laid-Open No. 2022-51000

### SUMMARY

### Problem to be Solved by the Invention

In the SAW filter, as a piezoelectric element transmitting an elastic wave gets thinner and thinner, a propagation speed thereof increases, and energy loss decreases. However, improvement of characteristics of the SAW filter is approaching a limit due to rise of a frequency in a frequency range to be used.

In order to solve the above problems, an object of the present disclosure is to provide a frequency filter capable of being operated in a high frequency range.

### Means to Solve the Problem

A frequency filter according to the present disclosure includes a medium layer, an input-side comb-tooth electrode and an output-side comb-tooth electrode. The medium layer has flexoelectric characteristics. The input-side comb-tooth electrode is provided on the medium layer. The output-side comb-tooth electrode is provided on the medium layer. The medium layer can generate an elastic wave in the medium layer in accordance with an input electrical field in the input-side comb-tooth electrode and an output electrical field corresponding to the elastic wave in the output-side comb-tooth electrode.

### Effects of the Invention

According to the present disclosure, the frequency filter which can be operated in a high frequency range is provided.

These and other objects, features, aspects and advantages of the present disclosure will become more apparent from the following detailed description when taken in conjunction with the accompanying diagrams.

### BRIEF DESCRIPTION OF DRAWINGS

FIG. 1 is a perspective view illustrating a configuration of a frequency filter according to an embodiment 1.

FIG. 2 is a perspective view illustrating a configuration of a frequency filter according to an embodiment 2.

FIG. 3 is a plan view illustrating a configuration of an input-side comb-tooth electrode according to the embodiment 2.

FIG. 4 is a plan view illustrating a configuration of an input-side comb-tooth electrode according to a modification example 1 of the embodiment 2.

### DESCRIPTION OF EMBODIMENT(S)

### Embodiment 1

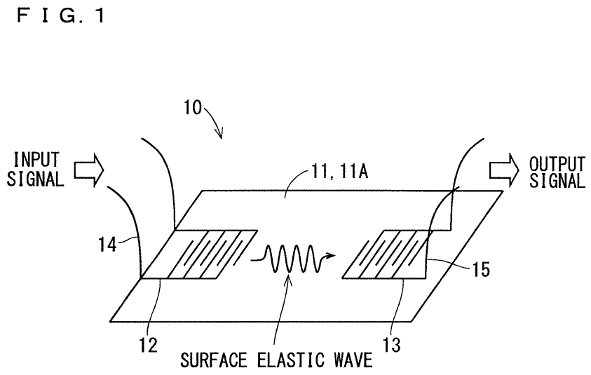

FIG. 1 is a perspective view illustrating a configuration of a frequency filter 10 according to an embodiment 1. The frequency filter 10 is a surface acoustic wave (SAW) filter for high frequency.

The frequency filter 10 includes a medium layer 11, an input-side comb-tooth electrode 12, an output-side comb-tooth electrode 13, an input-side wiring 14, and an output-side wiring 15.

The medium layer 11 has flexoelectric characteristics. In the present specification, flexoelectric effect and inverse flexoelectric effect are collectively referred to as flexoelectric characteristics, such characteristics are also simply referred to as flexoelectric effect.

In the medium layer 11 having the flexoelectric characteristics, an electrical field occurs in accordance with strain gradient in the medium layer 11. This is referred to as flexoelectric effect. Strain gradient occurs in the medium layer 11 in accordance with electrical field. This is referred to as inverse flexoelectric effect.

The medium layer 11 generates an elastic wave corresponding to input electrical field in the input-side comb-tooth electrode 12 and excited by the inverse flexoelectric characteristics of the medium layer 11. The elastic wave propagates through the medium layer 11. Then, the medium layer 11 generates output electrical field corresponding to an elastic wave in the output-side comb-tooth electrode 13 and converted from an elastic wave by flexoelectric characteristics of the medium layer 11. The elastic wave propagating through the medium layer 11 is also referred to as a surface elastic wave.

The medium layer 11 in the embodiment 1 is formed by a single-layered or multi-layered two-dimensional thin films 11A. The two-dimensional thin films 11A have a two-dimensional bonding structure of atoms. The multi-layered two-dimensional thin films have a structure in which the single-layered two-dimensional thin film is stacked. Van der Waals' force is applied between the layers, and the multi-layered two-dimensional thin films are bonded to each other by van der Waals' force. The two-dimensional thin film 11A is formed by an insulating material or a semiconductor material, for example. The two-dimensional thin film 11A is formed of hexagonal boron nitride, molybdenum disulfide, and molybdenum telluride, for example. A thickness of the two-dimensional thin film 11A is equal to a single atom or 10 nm or less. The thickness of the two-dimensional thin film 11A is such that flexoelectric characteristics in that two-dimensional thin film 11A are larger than piezoelectric characteristics. The medium layer 11 is not limited to the two-dimensional thin film 11A. The medium layer 11 may be formed of a non-piezoelectric insulating material.

The input-side comb-tooth electrode 12 is provided on the two-dimensional thin film 11A. The input-side comb-tooth electrode 12 includes two comb teeth. The two comb teeth are disposed to face each other to form an embedded structure. The comb teeth in the input-side comb-tooth electrode 12 include one or more groups of parallel parts. The input-side comb-tooth electrode 12 is formed of a conductive material. The input-side comb-tooth electrode 12 is formed of copper, gold, aluminum, or graphene, for example. An input signal is inputted to the input-side comb-tooth electrode 12. Electrical filed corresponding to an interval between the comb teeth is formed in the comb teeth of the input-side comb-tooth electrode 12.

The output-side comb-tooth electrode 13 is provided on the same two-dimensional thin film 11A. The output-side comb-tooth electrode 13 includes two comb teeth. The two comb teeth are disposed to face each other to form an embedded structure. The comb teeth in the output-side comb-tooth electrode 13 are provided in parallel to the comb teeth in the input-side comb-tooth electrode 12. An interval between the comb teeth in the input-side comb-tooth electrode 12 is the same as an interval between the comb teeth in the output-side comb-tooth electrode 13. The comb teeth in the output-side comb-tooth electrode 13 include one or more groups of parallel parts. The output-side comb-tooth electrode 13 is formed of a conductive material. The output-side comb-tooth electrode 13 is formed of copper, gold, aluminum, or graphene, for example. An elastic wave generated in the input-side comb-tooth electrode 12 reaches the output-side comb-tooth electrode 13. Electrical filed corresponding to the elastic wave corresponding to the output-side comb-tooth electrode 13 is formed in the comb teeth of the output-side comb-tooth electrode 13.

The input-side wiring 14 is electrically connected to the input-side comb-tooth electrode 12. An input signal is applied to the input-side comb-tooth electrode 12 via the input-side wiring 14.

The output-side wiring 15 is electrically connected to the output-side comb-tooth electrode 13. An output signal corresponding to the electrical field in the output-side comb-tooth electrode 13 is taken outside via the output-side wiring 15.

A method of manufacturing the frequency filter 10 is described next. The medium layer 11 is formed firstly. The medium layer 11 has flexoelectric characteristics. The single-layered or multi-layered two-dimensional thin film 11A is formed herein. The two-dimensional thin film 11A is manufactured by a scotch tape method or a molecular beam epitaxy method. Subsequently, the input-side comb-tooth electrode 12 and the output-side comb-tooth electrode 13 are deposited on the two-dimensional thin film 11A.

An operation of the frequency filter 10 is described next. An input signal including a plurality of frequency components is inputted to the input-side comb-tooth electrode 12 from an external circuit through the input-side wiring 14. The input signal is a high frequency signal, and includes a random frequency component, for example. Electrical field having a correspondence relationship with the interval of the comb teeth is generated between the comb teeth of the input-side comb-tooth electrode 12. Strain gradient based on the electrical field occurs in the two-dimensional thin film 11A by the inverse flexoelectric effect, and an elastic wave is excited.

The elastic wave propagates through the two-dimensional thin film 11A to reach the output-side comb-tooth electrode 13. Strain gradient corresponding to a frequency of the elastic wave occurs in the two-dimensional thin film 11A in the output-side comb-tooth electrode 13. Electrical field corresponding to the strain gradient is generated between the comb teeth by the flexoelectric effect. An output signal corresponding to the electrical field is outputted outside via the output-side wiring 15.

As described above, only the output signal of a specific frequency is extracted from the input signal including the plurality of frequency components. That is to say, only the specific frequency passes through the frequency filter 10.

A frequency of a signal outputted outside is calculated by the following expression (1).

$$\begin{matrix}[ Expression 1 ] & \\ f = \frac{v}{λ} & ( 1 )\end{matrix}$$

Herein, f expresses a frequency, v expresses a propagation speed of an elastic wave, and λ expresses a wavelength of the elastic wave excited in the input-side comb-tooth electrode 12, that is to say, the interval of the comb teeth.

The propagation speed v is calculated by the following expression (2).

$$\begin{matrix}[ Expression 2 ] & \\ v = \sqrt{\frac{E}{ρ}} & ( 2 )\end{matrix}$$

Herein, p expresses a density, and E expresses a degree of elasticity. As the propagation speed v gets larger and the interval of comb teeth 2 gets smaller, the frequency f increases.

As an outline of the above description, the frequency filter 10 in the embodiment 1 includes the medium layer 11, the input-side comb-tooth electrode 12, and the output-side comb-tooth electrode 13. The medium layer 11 has flexoelectric characteristics. The input-side comb-tooth electrode 12 is provided on the medium layer 11. The output-side comb-tooth electrode 13 is provided on the medium layer 11. The medium layer 11 can generate the elastic wave in the medium layer 11 in accordance with the input electrical field in the input-side comb-tooth electrode 12 and the output electrical field corresponding to the elastic wave in the output-side comb-tooth electrode 13.

When the medium layer 11 is the two-dimensional thin film 11A, a device can be thinned to an atomic size. The elastic wave does not propagate in a thickness direction of the two-dimensional thin film 11A. An existence probability of defect in the medium layer 11 is reduced by decrease of the size of the medium layer 11 through which the elastic wave propagates. Thus, decay of the elastic wave hardly occurs. Even when the medium layer 11 is the multi-layered two-dimensional thin film 11A, friction between the layers is small. Thus, dissipation of energy is small. As described above, the elastic wave is hardly decayed in the frequency filter 10. The frequency filter 10 can be applied to a high frequency device. The two-dimensional thin film 11A electrically responds to deformation more sensitively than a bulk material. This is also an advantage.

In the frequency filter in which the piezoelectric element is used, a piezoelectric effect disappear when a dimension thereof is reduced to several nanometers or less. Thus, there is a limit to improvement of performance of the high frequency device using the piezoelectric element. In the meanwhile, the frequency filter 10 in the embodiment 1 can also be applied to a device using a high frequency of several GHz or more, and a size of a device can also be reduced.

### Embodiment 2

In an embodiment 2, the same reference numeral is assigned to a constituent element similar to that in the embodiment 1.

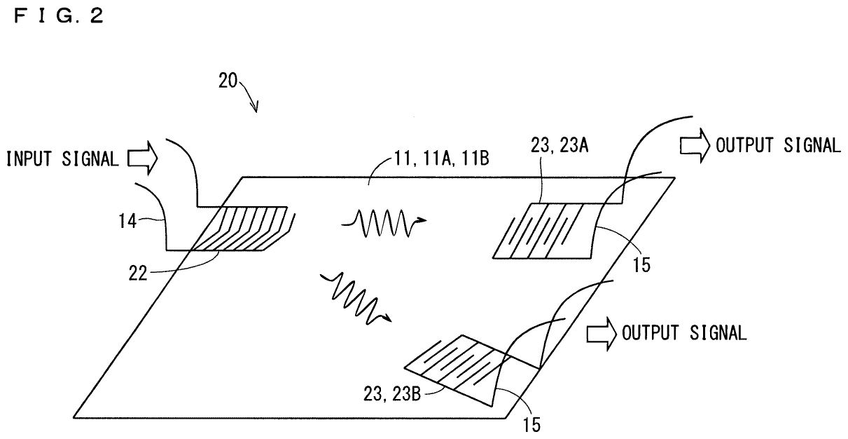

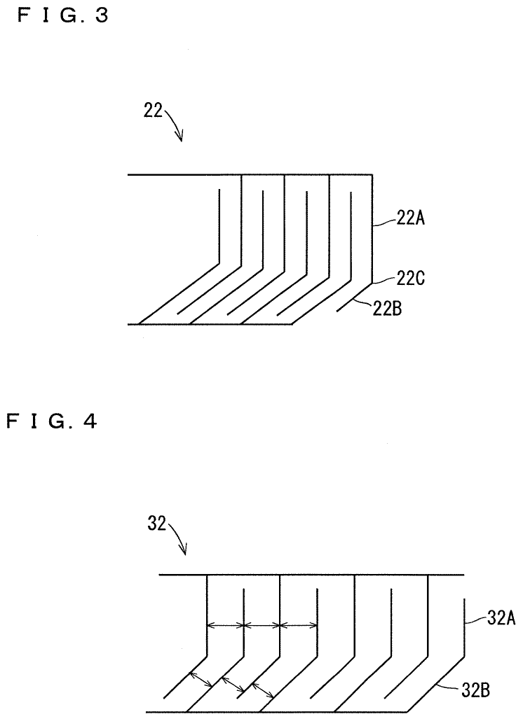

FIG. 2 is a perspective view illustrating a configuration of a frequency filter 20 according to the embodiment 2. The frequency filter 20 includes an input-side comb-tooth electrode 22 and an output-side comb-tooth electrode 23. FIG. 3 is a plan view illustrating a configuration of the input-side comb-tooth electrode 22 according to the embodiment 2.

The input-side comb-tooth electrode 22 includes a first input-side comb-tooth part 22A, a second input-side comb-tooth part 22B, and a bending part 22C. The second input-side comb-tooth part 22B is electrically connected to the first input-side comb-tooth part 22A with an angle with respect to the first input-side comb-tooth part 22A. The first input-side comb-tooth part 22A in the embodiment 2 is connected to the second input-side comb-tooth part 22B via the bending part 22C. Comb teeth in the first input-side comb-tooth part 22A are parallel to each other, and comb teeth in the second input-side comb-tooth part 22B are also parallel to each other. An interval of the comb teeth in the second input-side comb-tooth part 22B is the same as that in the first input-side comb-tooth part 22A.

The output-side comb-tooth electrode 23 includes a first output-side comb-tooth electrode 23A and a second output-side comb-tooth electrode 23B. The second output-side comb-tooth electrode 23B is provided separately from the first output-side comb-tooth electrode 23A. The first output-side comb-tooth electrode 23A includes a comb tooth in parallel to the first input-side comb-tooth electrode 22A. The second output-side comb-tooth electrode 23B includes a comb tooth in parallel to the second input-side comb-tooth electrode 22B.

An input signal including a random frequency component is inputted to the input-side comb-tooth electrode 22 from an external circuit through the input-side wiring 14. The input signal is a high frequency signal. Electrical field having a correspondence relationship with an interval of comb teeth is generated between the comb teeth in the first input-side comb-tooth part 22A and the comb teeth in the second input-side comb-tooth part 22B. Strain gradient based on the electrical field occurs in the two-dimensional thin film 11A by the inverse flexoelectric effect, and an elastic wave is excited. In the embodiment 2, an interval of the comb teeth in the first input-side comb-tooth part 22A is the same as that in the second input-side comb-tooth part 22B. Thus, a wavelength of the elastic wave excited in the first input-side comb-tooth part 22A is the same as that excited in the second input-side comb-tooth part 22B. In Expression (1), the wavelength 2 of the first input-side comb-tooth part 22A and the wavelength 2 of the second input-side comb-tooth part 22B are the same as each other.

The elastic wave generated in the first input-side comb-tooth part 22A propagates through the two-dimensional thin film 11A to reach the first output-side comb-tooth electrode 23A, for example. The elastic wave generated in the second input-side comb-tooth part 22B propagates through the two-dimensional thin film 11A to reach the second output-side comb-tooth electrode 23B, for example. In each of the first output-side comb-tooth electrode 23A and the second output-side comb-tooth electrode 23B, strain gradient corresponding to a frequency of the elastic wave thereof occurs in the two-dimensional thin film 11A. Electrical field corresponding to the strain gradient is generated between the comb teeth of each of the first output-side comb-tooth electrode 23A and the second output-side comb-tooth electrode 23B by the flexoelectric effect. An output signal corresponding to the electrical field is output outside via the output-side wiring 15.

Accordingly, only the output signal of a specific frequency is extracted from the input signal including the random frequency component. That is to say, only the specific frequency passes through the frequency filter 20. In the embodiment 2, since the interval of the comb teeth of the first input-side comb-tooth part 22A is the same as that of the second input-side comb-tooth part 22B, two output signals having the same frequency are obtained from two positions.

### Modification Example 1 of Embodiment 2

FIG. 4 is a plan view illustrating a configuration of an input-side comb-tooth electrode 32 according to a modification example 1 of the embodiment 2.

The input-side comb-tooth electrode 32 includes a first input-side comb-tooth part 32A and a second input-side comb-tooth part 32B. The second input-side comb-tooth part 32B is electrically connected to the first input-side comb-tooth part 32A with an angle with respect to the first input-side comb-tooth part 32A. An interval of the comb teeth in the second input-side comb-tooth part 32B is different from that in the first input-side comb-tooth part 32A.

In this case, a distribution of the electrical field generated between the comb teeth of the first input-side comb-tooth part 32A is different from that generated between the comb teeth of the second input-side comb-tooth part 32B. Also with regard to the inverse flexoelectric effect, strain gradient occurring in the first input-side comb-tooth part 32A is different from that occurring in the second input-side comb-tooth part 32B. Thus, a wavelength of the elastic wave excited in the first input-side comb-tooth part 32A is different from that excited in the second input-side comb-tooth part 32B. In Expression (1), the wavelength λ of the first input-side comb-tooth part 32A and the wavelength λ of the second input-side comb-tooth part 32B are different from each other.

The elastic wave generated in the first input-side comb-tooth part 32A propagates through the two-dimensional thin film 11A to reach the first output-side comb-tooth electrode 23A, for example. The elastic wave generated in the second input-side comb-tooth part 32B propagates through the two-dimensional thin film 11A to reach the second output-side comb-tooth electrode 23B, for example. In each of the first output-side comb-tooth electrode 23A and the second output-side comb-tooth electrode 23B, strain gradient corresponding to a frequency of the elastic wave thereof occurs in the two-dimensional thin film 11A. Electrical field corresponding to the strain gradient is generated between the comb teeth of each of the first output-side comb-tooth electrode 23A and the second output-side comb-tooth electrode 23B by the flexoelectric effect. An output signal corresponding to the electrical field is output outside via the output-side wiring 15. A frequency of the output signal outputted from the first output-side comb-tooth electrode 23A is different from that outputted from the second output-side comb-tooth electrode 23B.

In this manner, two output signals each having the frequency different from each other are obtained for one input signal.

### Modification Example 2 of Embodiment 2

The two-dimensional thin film 11A may have anisotropy in a degree of elasticity in a plane of the two-dimensional thin film 11A. In this case, the propagation speed v of the elastic wave in Expression (2) is different depending on a propagation direction thereof. Thus, the frequency of the elastic wave in Expression (1) is also different depending on the propagation direction.

In such a configuration, even when the interval of the comb teeth of the second input-side comb-tooth part 22B is the same as that of the first input-side comb-tooth part 22A, two output signals each having the frequency different from each other are obtained.

### Embodiment 3

In an embodiment 3, the same reference numeral is assigned to a constituent element similar to that in the embodiment 1 or 2.

The medium layer 11 in the embodiment 3 is formed of an insulating substrate (not shown) made up of an insulating material. When the medium layer 11 is the insulating substrate made up of the insulating material, flexoelectric effect and inverse flexoelectric effect appear in the insulating material. The input-side comb-tooth electrode 22 and the output-side comb-tooth electrode 23 are provided on the insulating substrate.

In the manner similar to the embodiment 2, with reference to FIG. 3, the input-side comb-tooth electrode 22 includes the first input-side comb-tooth part 22A, the second input-side comb-tooth part 22B, and the bending part 22C. The second input-side comb-tooth part 22B is electrically connected to the first input-side comb-tooth part 22A with an angle with respect to the first input-side comb-tooth part 22A. The first input-side comb-tooth part 22A in the embodiment 3 is connected to the second input-side comb-tooth part 22B via the bending part 22C. The comb teeth in the first input-side comb-tooth part 22A are parallel to each other, and the comb teeth in the second input-side comb-tooth part 22B are also parallel to each other. The interval of the comb teeth in the second input-side comb-tooth part 22B may be the same as or different from that in the first input-side comb-tooth part 22A.

With reference to FIG. 2, the output-side comb-tooth electrode 23 includes the first output-side comb-tooth electrode 23A and the second output-side comb-tooth electrode 23B. The second output-side comb-tooth electrode 23B is provided separately from the first output-side comb-tooth electrode 23A. The first output-side comb-tooth electrode 23A includes the comb tooth in parallel to the first input-side comb-tooth electrode 22A. The second output-side comb-tooth electrode 23B includes the comb tooth in parallel to the second input-side comb-tooth electrode 22B.

The input signal including the random frequency component is inputted to the input-side comb-tooth electrode 22 from the external circuit through the input-side wiring 14. The input signal is the high frequency signal. The electrical field having the correspondence relationship with the interval of the comb teeth is generated between the comb teeth in the first input-side comb-tooth part 22A and the comb teeth in the second input-side comb-tooth part 22B. The strain gradient based on the electrical field occurs in the insulating material by the inverse flexoelectric effect, and the elastic wave is excited. When the interval of the comb teeth in the first input-side comb-tooth part 22A and the interval of the comb teeth in the second input-side comb-tooth part 22B are the same as each other, the elastic wave having the same wavelength is excited. In this case, the wavelength λ has the same value in Expression (1). In the meanwhile, when the interval of the comb teeth in the first input-side comb-tooth part 22A and the interval of the comb teeth in the second input-side comb-tooth part 22B are different from each other, the elastic waves each having the different wavelength are excited. In this case, the wavelength λ has the different value in Expression (1).

The elastic wave propagates through the insulating substrate 11B made up of the insulating material to reach the first output-side comb-tooth electrode 23A and the second output-side comb-tooth electrode 23B. The strain gradient corresponding to the frequency of the elastic wave occurs in each of the first output-side comb-tooth electrode 23A and the second output-side comb-tooth electrode 23B. Electrical field corresponding to the strain gradient is generated between the comb teeth of each of the first output-side comb-tooth electrode 23A and the second output-side comb-tooth electrode 23B by the flexoelectric effect. The output signal corresponding to the electrical field is output outside via the output-side wiring 15.

In the manner similar to the embodiment 2, two output signals having the same frequency or two output signals each having the frequency different from each other are obtained for one input signal including the random frequency component. Accordingly, the number of components is reduced compared with a case where an electrical circuit is formed to obtain two output signals.

Although the present disclosure is described in detail, the foregoing description is in all aspects illustrative and does not restrict the invention. It is therefore understood that numerous modification examples not illustrated can be devised.

Each embodiment can be arbitrarily combined, or each embodiment can be appropriately varied or omitted in the present disclosure.

### EXPLANATION OF REFERENCE SIGNS

10 frequency filter, 11 medium layer, 11A two-dimensional thin film, 12 input-side comb-tooth electrode, 13 output-side comb-tooth electrode, 14 input-side wiring, 15 output-side wiring, 20 frequency filter, 22 input-side comb-tooth electrode, 22A first input-side comb-tooth part, 22B second input-side comb-tooth part, 22C bending part, 23 output-side comb-tooth electrode, 23A first output-side comb-tooth electrode, 23B second output-side comb-tooth electrode, 32 input-side comb-tooth electrode, 32A first input-side comb-tooth part, 32B second input-side comb-tooth part.

1. A frequency filter, comprising:
a medium layer having flexoelectric characteristics;
an input-side comb-tooth electrode provided on the medium layer; and
an output-side comb-tooth electrode provided on the medium layer, wherein
the medium layer includes a single-layered or multi-layered two-dimensional thin film, and
the flexoelectric characteristics in the medium layer are larger than piezoelectric characteristics in the two-dimensional thin film.

2.-3. (canceled)

4. The frequency filter according to claim 1, wherein
a thickness of the two-dimensional thin film is equal to a single atom or 10 nm or less.

5. The frequency filter according to claim 1, wherein
the two-dimensional thin film is formed of any one of hexagonal boron nitride, molybdenum disulfide, and molybdenum telluride.

6. The frequency filter according to claim 1, wherein
the two-dimensional thin film has anisotropy in a degree of elasticity in a plane of the two-dimensional thin film.

7. The frequency filter according to claim 1, wherein
the medium layer is formed of a non-piezoelectric insulating material.

8. The frequency filter according to claim 1, wherein
the input-side comb-tooth electrode and the output-side comb-tooth electrode are formed of any one of copper, gold, aluminum, and graphene.

9. The frequency filter according to claim 1, wherein
comb teeth in the output-side comb-tooth electrode are provided in parallel to comb teeth in the input-side comb-tooth electrode.

10. The frequency filter according to claim 1, wherein
an interval between the comb teeth in the output-side comb-tooth electrode is a same as an interval between the comb teeth in the input-side comb-tooth electrode.

11. The frequency filter according to claim 1, wherein
the input-side comb-tooth electrode includes:
a first input-side comb-tooth part; and
a second input-side comb-tooth part electrically connected to the first input-side comb-tooth part with an angle with respect to the first input-side comb-tooth part, and
the output-side comb-tooth electrode includes:
a first output-side comb-tooth electrode including a comb tooth in parallel to the first input-side comb-tooth part; and
a second output-side comb-tooth electrode provided separately from the first output-side comb-tooth electrode and including a comb tooth in parallel to the second input-side comb-tooth part.

12. The frequency filter according to claim 11, wherein
an interval of the comb teeth in the second input-side comb-tooth part is a same as an interval of the comb teeth in the first input-side comb-tooth part.

13. The frequency filter according to claim 11, wherein
an interval of the comb teeth in the second input-side comb-tooth part is different from an interval of the comb teeth in the first input-side comb-tooth part.

14. The frequency filter according to claim 1, further comprising:
an input-side wiring electrically connected to the input-side comb-tooth electrode; and
an output-side wiring electrically connected to the output-side comb-tooth electrode.

15. The frequency filter according to claim 1, wherein
the medium layer includes an insulating substrate made up of an insulating material.

16. A method of manufacturing a frequency filter, comprising steps of:
forming a medium layer having flexoelectric characteristics; and
depositing the input-side comb-tooth electrode and the output-side comb-tooth electrode on the medium layer, wherein
the medium layer includes a single-layered or multi-layered two-dimensional thin film, and
the flexoelectric characteristics in the medium layer are larger than piezoelectric characteristics in the two-dimensional thin film.

17. (canceled)
